(19) United States
(12) Patent Application Publication
(10) Pub. No.: US 2016/0343969 A1
(43) Pub. Date: Nov. 24, 2016

(54) FLEXIBLE OLED DISPLAY DEVICE AND MANUFACTURE METHOD THEREOF

(71) Applicant: SHENZHEN CHINA STAR OPTOELECTRONICS TECHNOLOGY CO., LTD., Shenzhen, Guangdong (CN)

(72) Inventors: Weijing ZENG, Shenzhen, Guangdong (CN); Taipi WU, Shenzhen, Guangdong (CN)

(73) Assignee: Shenzhen China Star Optoelectronics Technology Co., Ltd., Shenzhen, Guangdong (CN)

(21) Appl. No.: 14/424,426

(22) PCT Filed: Feb. 9, 2015
(86) PCT No.: PCT/CN2015/072488

§ 371 Date: Feb. 26, 2015

(30) Foreign Application Priority Data
Dec. 12, 2014 (CN) 201410768215.8

(51) Int. Cl. H01L 51/52; H01L 27/32; H01L 51/00; H01L 51/56

(52) U.S. Cl. CPC H01L 51/524; H01L 51/5206; H01L 51/5221; H01L 51/56; H01L 27/3244; H01L 51/0021; H01L 2251/5338; H01L 2251/301; H01L 2227/323

(57) ABSTRACT

The present invention provides a flexible OLED display device and a manufacture method thereof, and the flexible OLED display device comprises a flexible OLED substrate (100) and a flexible package cover plate (200). By employing the package cover plate (200) comprising an isolation layer (201), a flexible metal layer (202) and a rollable hard coating layer (203) to implement package, and utilizing the excellent abilities of anti-water, anti-oxygen and extensibility of the flexible metal layer (202), the flexible OLED display device can be protected and does not react with the external water and oxygen to raise the lighting efficiency of the flexible OLED display device and extending the usage lifetime of the flexible OLED display device.

### FIELD OF THE INVENTION

The present invention relates to a display technology field, and more particularly to a flexible OLED display device and a manufacture method thereof.

### BACKGROUND OF THE INVENTION

Organic Light Emitting Diode (OLED) possesses extremely excellent display performance and properties of self-illumination, simple structure, ultra thin, fast response speed, wide view angle, low power consumption and capability of realizing flexible display.

The illuminating principle of OLED is the phenomenon that is the illumination due to the carrier injection and recombination under the electric field driving of organic semiconductor illuminating material and illuminating material. Specifically, the OLED display element generally utilizes the ITO transparent electrode and the metal electrode respectively as the anode and the cathode of the Display. Under certain voltage driving, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. The latter can illuminate after the radiative relaxation.

Because the organic material can easily react with water and oxygen, the OLED display panel has extremely high demands for the package as being the display element based on the organic material. For realizing commercial application, the OLED elements demand the usage lifetime≧10,000 hours, and the package requirements of satisfying water penetration rate≦10-6 g/m2/day and oxygen penetration rate≦10-5 cc/m2/day (1 atm) are essential for achieving the aforementioned demand of the usage lifetime.

The OLED display element, which is bendable, light weight, portable, manufactured with the flexible substrate is an important development prospect for the present display technology, and the package result determines the light efficiency and usage lifetime of the flexible OLED display device. In prior arts, the thin film package is common for the flexible OLED, i.e. forming an organic/inorganic repeated superposition protective layer on the OLED element. However, the abilities of anti-water, anti-oxygen of the thin film package which is directly accomplished on the OLED element is poor and can easily damage the OLED element.

### SUMMARY OF THE INVENTION

An objective of the present invention is to provide a flexible OLED display device, of which the seal is great and anti-water, anti-oxygen for preventing the damage to the organic OLED, promoting the package result of the OLED display device and extending the usage lifetime of the OLED display device.

Another objective of the present invention is to provide a manufacture method of a flexible OLED display device, of which the manufacture method is simple and easy for operation, for manufacturing a well sealed flexible OLED display device capable of being anti-water, anti-oxygen to promote the quality of the flexible OLED display device.

For realizing the aforesaid objective, the present invention provides a flexible OLED display device, comprising a flexible OLED substrate and a flexible package cover plate;

wherein the flexible OLED substrate comprises a transparent substrate, an anode metal layer located on the flexible substrate, an organic layer located on the anode metal layer and a cathode metal layer located on the organic layer;

the flexible package cover plate comprises an isolation layer, a rollable hard coating layer and a flexible metal layer located between the isolation layer and the rollable hard coating layer;

the flexible package cover plate is pressed on the flexible OLED substrate, and the isolation layer of the flexible package cover plate and the cathode metal layer of the flexible OLED substrate are adhered with assembly glue.

The flexible substrate is a transparent TFT substrate, and the anode metal layer is a transparent electrode.

The cathode metal layer is a reflecting electrode.

Material of the isolation layer is isolating inorganic material or isolating organic polymer material.

Material of the flexible metal layer is one of the aluminum, silver, copper, titanium.

The present invention further provides a manufacture method of a flexible OLED display device, comprising steps of:

step 1, providing a flexible substrate, and sequentially deposing an anode metal layer, an organic layer and a cathode metal layer on the transparent substrate to form a flexible OLED substrate;

step 2, providing a flexible metal slice as being a flexible metal layer employed to be a flexible package cover plate, and manufacturing an isolation layer at one side of the flexible metal layer, and locating a rollable hard coating layer at the other side of the flexible metal layer to form the flexible package cover plate;

step 3, adhering the manufactured cathode metal layer of the flexible OLED substrate and the isolation layer of the flexible package cover plate with assembly glue in a vacuum environment to form a sealed flexible OLED display device.

In the step 1, the flexible substrate is a transparent TFT substrate, and the anode metal layer is a transparent electrode, and the cathode metal layer is a reflecting electrode.

In the step 2, the isolation layer is isolating inorganic material, and manufactured by sputtering, chemical deposition or thermal evaporating.

In the step 2, the isolation layer is isolating organic polymer material, and formed by coating isolating organic polymer precursor material on the flexible metal layer and baking, curing the same.

In the step 2, material of the flexible metal layer is one of the aluminum, silver, copper, titanium.

The present invention further provides a manufacture method of a flexible OLED display device, comprising a flexible OLED substrate and a flexible package cover plate;

wherein the flexible OLED substrate comprises a flexible substrate, an anode metal layer located on the flexible substrate, an organic layer located on the anode metal layer and a cathode metal layer located on the organic layer;

the flexible package cover plate comprises an isolation layer, a rollable hard coating layer and a flexible metal layer located between the isolation layer and the rollable hard coating layer;

the flexible package cover plate is pressed on the flexible OLED substrate, and the isolation layer of the flexible package cover plate and the cathode metal layer of the flexible OLED substrate are adhered with assembly glue;

wherein the flexible substrate is a transparent TFT substrate, and the anode metal layer is a transparent electrode;

wherein the cathode metal layer is a reflecting electrode.

The benefits of the present invention are: the present invention provides a flexible OLED display device and a manufacture method thereof, by employing the package cover plate comprising an isolation layer, a flexible metal layer and a rollable hard coating layer to implement package, and utilizing the excellent abilities of anti-water, anti-oxygen and extensibility of the flexible metal layer, the flexible OLED display device can be protected and does not react with the external water and oxygen to raise the lighting efficiency of the flexible OLED display device and extending the usage lifetime of the flexible OLED display device.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structural diagram of a flexible OLED display device according to the present invention;

FIG. 2 is a flowchart of a manufacture method of the flexible OLED display device according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

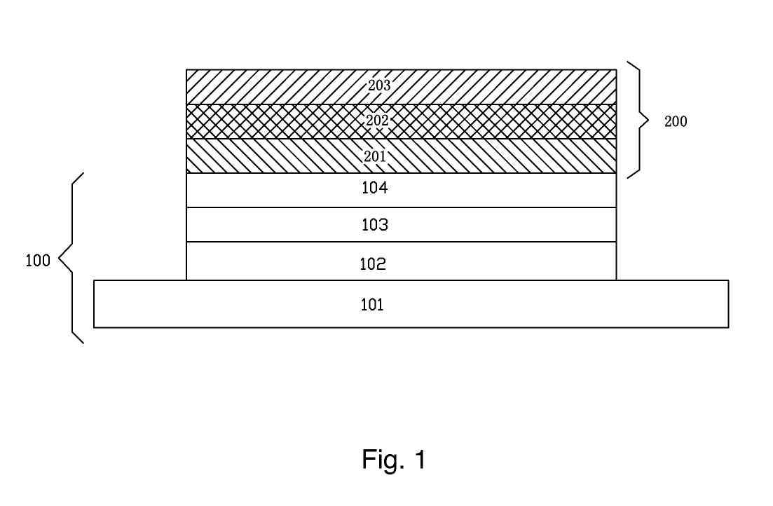

Please refer to FIG. 1. The present invention provides a flexible OLED display device, comprising a flexible OLED substrate 100 and a flexible package cover plate 200;

the flexible OLED substrate 100 comprises a flexible substrate 101, an anode metal layer 102 located on the flexible substrate 101, an organic layer 103 located on the anode metal layer 102 and a cathode metal layer 104 located on the organic layer 103;

Specifically, the flexible substrate 101 is a transparent TFT substrate, and the anode metal layer 102 is a transparent electrode, and the cathode metal layer 104 is a reflecting electrode; the organic layer 103 comprises: a Hole Transporting Layer located on the anode metal layer 102, an emitting material layer located on the Hole Transporting Layer, an Electron Transport Layer located on the emitting material layer, as a certain driving voltage is applied between the anode metal layer 102 and the cathode metal layer 104, the Electron and the Hole are respectively injected into the Electron and Hole Transporting Layers from the cathode metal layer 104 and the anode metal layer 102, and the Electron and the Hole respectively migrate from the Electron and Hole Transporting Layers to the Emitting layer and bump into each other in the Emitting layer to form an exciton to excite the emitting molecule. The latter can illuminate after the radiative relaxation. The light directly goes out by passing through the transparent anode metal layer 102 or goes out by passing through the transparent anode metal layer 102 after being reflected by the reflective cathode metal layer 104.

The flexible package cover plate 200 comprises an isolation layer 201, a rollable hard coating layer 203 and a flexible metal layer 202 located between the isolation layer 201 and the rollable hard coating layer 203;

wherein the isolation layer 201 is manufactured by isolating material, and the isolating material can be SiO₂, SiN_{X}, Al₂O₃, etc., or can be isolating organic polymer material. The isolation layer 201 is capable of preventing short circuit caused by the contact between the flexible metal layer 202 and the cathode metal layer 104, and meanwhile possesses a certain abilities of anti-water, anti-oxygen.

The flexible package cover plate 200 is pressed on the flexible OLED substrate 100, and the isolation layer 201 of the flexible package cover plate 200 and the cathode metal layer 104 of the flexible OLED substrate 100 are adhered with assembly glue.

Preferably, material of the flexible metal layer 202 is one of the aluminum, silver, copper, titanium, and material of the flexible metal layer 202 demands to possess well extensibility and compactness for realizing the functions of flexible display and anti-water, anti-oxygen.

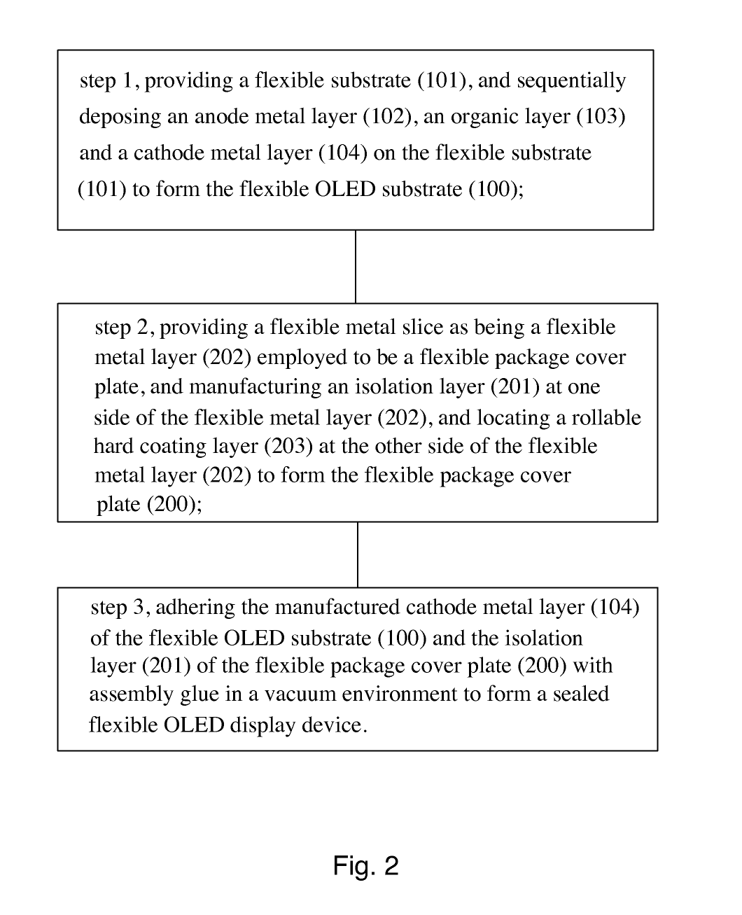

Please refer to FIG. 2. The present invention further provides a manufacture method of a flexible OLED display device, comprising steps of:

step 1, providing a flexible substrate 101, and sequentially deposing an anode metal layer 102, an organic layer 103 and a cathode metal layer 104 on the flexible substrate 101 to form the flexible OLED substrate 100;

In the step 1, the flexible substrate 101 is a transparent TFT substrate, and the anode metal layer 102 is manufactured with transparent conductive material, such as ITO (Indium Tin Oxide) and employed as a transparent electrode; the cathode metal layer 104 is manufactured with metal material, such as aluminum, magnesium, silver and employed as a reflecting electrode; the organic layer 103 comprises: a Hole Transporting Layer located on the anode metal layer 102, an emitting material layer located on the Hole Transporting Layer, an Electron Transport Layer located on the emitting material layer.

step 2, providing a flexible metal slice as being a flexible metal layer 202 employed to be a flexible package cover plate, and manufacturing an isolation layer 201 at one side of the flexible metal layer 202, and locating a rollable hard coating layer 203 at the other side of the flexible metal layer 202 to form the flexible package cover plate 200;

the flexible metal layer 202 is metal material possessing extensibility and well compactness, such as aluminum, silver, copper or titanium, and the well extensibility can allow the OLED substrate to realize flexible display, and the well compactness can resist the water and oxygen to protect the organic material in the flexible OLED display device.

Material selected for the isolation layer 201 demands to have insulativity to prevent short circuit between the flexible metal layer 202 and the cathode metal layer 104. Specifically, in the step 2, the isolation layer 201 can be isolating inorganic material, and manufactured by sputtering, chemical deposition or thermal evaporating, or can be isolating organic polymer material, and formed by coating polymer precursor material on the flexible metal layer 202 and baking, curing the same.

The rollable hard coating layer 203 comprises the protective metal slice having damage proof and isolating functions, which can be manufactured by any flexible material having the aforesaid functions, such as the organic polymer material, the isolating organic polymer material is formed by coating polymer precursor material on the flexible metal layer 202 and baking, curing the same.

step 3, adhering the manufactured cathode metal layer 104 of the flexible OLED substrate 100 and the isolation layer 201 of the flexible package cover plate 200 with assembly glue in a vacuum environment to form a sealed flexible OLED display device.

With the manufacture in the vacuum environment, it can be ensured that no air remains in the flexible OLED display device as the manufacture is accomplished, and the organic material in the flexible OLED display device is well protected.

In conclusion, the present invention provides a flexible OLED display device and a manufacture method thereof, by employing the package cover plate comprising an isolation layer, a flexible metal layer and a rollable hard coating layer to implement package, and utilizing the excellent abilities of anti-water, anti-oxygen and extensibility of the flexible metal layer, the flexible OLED display device can be protected and does not react with the external water and oxygen to raise the lighting efficiency of the flexible OLED display device and extending the usage lifetime of the flexible OLED display device.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A flexible OLED display device, comprising a flexible OLED substrate and a flexible package cover plate;
wherein the flexible OLED substrate comprises a flexible substrate, an anode metal layer located on the flexible substrate, an organic layer located on the anode metal layer and a cathode metal layer located on the organic layer;
the flexible package cover plate comprises an isolation layer, a rollable hard coating layer and a flexible metal layer located between the isolation layer and the rollable hard coating layer;
the flexible package cover plate is pressed on the flexible OLED substrate, and the isolation layer of the flexible package cover plate and the cathode metal layer of the flexible OLED substrate are adhered with assembly glue.

2. The flexible OLED display device according to claim 1, wherein the flexible substrate is a transparent TFT substrate, and the anode metal layer is a transparent electrode.

3. The flexible OLED display device according to claim 1, wherein the cathode metal layer is a reflecting electrode.

4. The flexible OLED display device according to claim 1, wherein material of the isolation layer is isolating inorganic material or isolating organic polymer material.

5. The flexible OLED display device according to claim 1, wherein material of the flexible metal layer is one of the aluminum, silver, copper, titanium.

6. A manufacture method of a flexible OLED display device, comprising steps of:
step 1, providing a flexible substrate, and sequentially deposing an anode metal layer, an organic layer and a cathode metal layer on the flexible substrate to form a flexible OLED substrate;
step 2, providing a flexible metal slice as being a flexible metal layer employed to be a flexible package cover plate, and manufacturing an isolation layer at one side of the flexible metal layer, and locating a rollable hard coating layer at the other side of the flexible metal layer to form the flexible package cover plate;
step 3, adhering the manufactured cathode metal layer of the flexible OLED substrate and the isolation layer of the flexible package cover plate with assembly glue in a vacuum environment to form a sealed flexible OLED display device.

7. The manufacture method of the flexible OLED display device according to claim 6, wherein in the step 1, the flexible substrate is a transparent TFT substrate, and the anode metal layer is a transparent electrode, and the cathode metal layer is a reflecting electrode.

8. The manufacture method of the flexible OLED display device according to claim 6, wherein in the step 2, the isolation layer is isolating inorganic material, and manufactured by sputtering, chemical deposition or thermal evaporating.

9. The manufacture method of the flexible OLED display device according to claim 6, wherein in the step 2, the isolation layer is isolating organic polymer material, and formed by coating polymer precursor material on the flexible metal layer and baking, curing the same.

10. The manufacture method of the flexible OLED display device according to claim 6, wherein in the step 2, material of the flexible metal layer is one of the aluminum, silver, copper, titanium.

11. A flexible OLED display device, comprising a flexible OLED substrate and a flexible package cover plate;
wherein the flexible OLED substrate comprises a flexible substrate, an anode metal layer located on the flexible substrate, an organic layer located on the anode metal layer and a cathode metal layer located on the organic layer;
the flexible package cover plate comprises an isolation layer, a rollable hard coating layer and a flexible metal layer located between the isolation layer and the rollable hard coating layer;
the flexible package cover plate is pressed on the flexible OLED substrate, and the isolation layer of the flexible package cover plate and the cathode metal layer of the flexible OLED substrate are adhered with assembly glue;
wherein the flexible substrate is a transparent TFT substrate, and the anode metal layer is a transparent electrode;
wherein the cathode metal layer is a reflecting electrode.

12. The flexible OLED display device according to claim 11, wherein material of the isolation layer is isolating inorganic material or isolating organic polymer material.

13. The flexible OLED display device according to claim 11, wherein material of the flexible metal layer is one of the aluminum, silver, copper, titanium.
